(19) United States
(12) Patent Application Publication
(10) Pub. No.: US 2012/0224334 A1
(43) Pub. Date: Sep. 6, 2012

(54) MOUNTING APPARATUS FOR DATA STORAGE DEVICE

(75) Inventor: HSIANG-WEI LIU, Tu-Cheng (TW)

(73) Assignee: HON HAI PRECISION INDUSTRY CO., LTD., Tu-Cheng (TW)

(21) Appl. No.: 13/095,901

(22) Filed: Apr. 28, 2011

(30) Foreign Application Priority Data
Mar. 2, 2011 (TW) 100106999

(51) Int. Cl. H05K 7/00; F16B 2/20; H05K 7/14

(52) U.S. Cl. 361/748; 248/316.7

(57) ABSTRACT

A mounting apparatus is provided to mount a data storage device includes a bracket and a number of fastening members. The bracket includes two opposite clamping arms to sandwich the data storage device. The fastening members extend through the clamping arms to be locked to the data storage device. Two resilient portions are respectively formed on a top and a bottom of each clamping arm.

### BACKGROUND

1. Technical Field

The disclosure relates to a mounting apparatus for a data storage device.

2. Description of Related Art

Generally speaking, in mounting a storage device to a computer, a bracket is first mounted in a computer enclosure, and then the storage device is attached to the bracket. During use of the computer, the storage device may vibrate and generate noise when the storage device is accessed. Moreover, the vibrations may cause the storage device bump against the bracket, which can potentially damage the data storage device.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a mounting apparatus, together with a data storage device.

FIG. 2 is an assembled, isometric view of FIG. 1.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

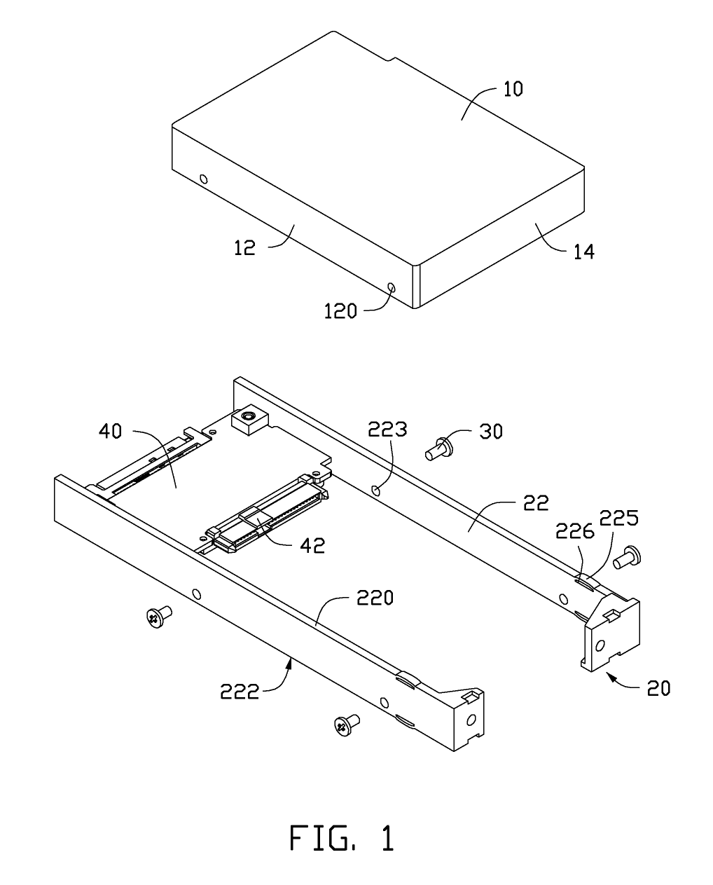

Referring to FIG. 1, an exemplary embodiment of a mounting apparatus is provided to mount a data storage device 10. The mounting apparatus includes a bracket 20, and a plurality of fastening members 30 to mount the data storage device 10 to the bracket 20. In this embodiment, each fastening member 30 is a screw.

The data storage device 10 includes two opposite sidewalls 12 and a front wall 14 perpendicularly connected between front ends of the sidewalls 12. Each sidewall 12 defines a plurality of mounting holes 120. A port (not show) is formed on a rear end of the data storage device 10.

The bracket 20 includes two opposite clamping arms 22. Each clamping arm 22 is substantially L-shaped, and defines a plurality of through holes 223 therein. Each clamping arm 22 defines two through slots 226 respectively parallel and adjacent to a top 220 and a bottom 222 of the clamping arm 22. Two substantially arc-shaped resilient portions 225 are formed on the top 220 and bottom 222 of the clamping arm 22. The resilient portion 225 on the top is located above the corresponding through slot 226, and the resilient portion 225 on the bottom is located below the corresponding through slot 226. In the other embodiments, a plurality of arc-shaped resilient portions 225 can directly extend from the top 220 and the bottom 222.

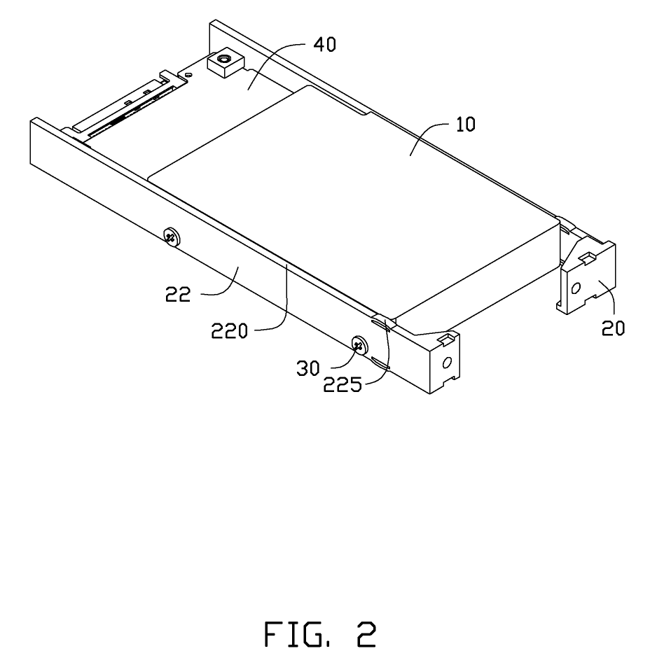

Referring to FIG. 2, in assembly, the data storage device 10 is sandwiched between the clamping arms 22, with the sidewalls 12 of the data storage device 10 resisting against the corresponding clamping arms 22. The fastening members 30 extend through the through holes 223 of the bracket 20 to be locked in the mounting holes 120. Thereby, the data storage device 10 is tightly mounted to the bracket 20. In this embodiment, a circuit board 40 is mounted between rear ends of the clamping arms 22 of the bracket 20. A connector 42 set on the circuit board 40 is electrically connected to the port of the data storage device 10.

In use, the assembly of the bracket 20 and the data storage device 10 is mounted in a rack of a computer. The resilient portions 225 of the bracket 20 resist against an inner wall of the rack. During vibration of the rack, the resilient portions 225 act as shock absorbers to protect the data storage device 10 from vibrations.

It is believed that the present embodiment and its advantages will be understood from the foregoing description, and it will be apparent that various changes may be made thereto without departing from the spirit and scope of the description or sacrificing all of their material advantages, the example hereinbefore described merely being exemplary embodiment.

What is claimed is:

1. A mounting apparatus for mounting a data storage device, the mounting apparatus comprising:
a bracket comprising two opposite clamping arms to sandwich the data storage device; and
a plurality of fastening members extending through the clamping arms to be locked to the data storage device;
wherein two resilient portions are respectively formed on a top and a bottom of each clamping arm.

2. The mounting apparatus of claim 1, wherein each clamping arm defines two through slots substantially parallel and adjacent to the top and the bottom of the clamping arm, respectively, the resilient portion on the top is located above the corresponding through slot, and the resilient portion on the bottom is located below the corresponding through slot.

3. The mounting apparatus of claim 1, wherein a circuit board is mounted to the bracket and sandwiched between rear ends of the clamping arms, to be electrically connected to the data storage device.
